(19) United States
(12) Patent Application Publication
(10) Pub. No.: US 2008/0188017 A1
(43) Pub. Date: Aug. 7, 2008

(54) Method of sorting dies using discrimination region

(75) Inventors: Young-Dae Kim, Seoul (KR); Yun-Ki Kim, Suwon-si (KR); Sung-Un Bae, Chungcheongnam-do (KR)

Correspondence Address: MILLS & ONELLO LLP, ELEVEN BEACON STREET, SUITE 605, BOSTON, MA, 02108, US

(73) Assignee: Samsung Electronics, Co., Ltd., Suwon-si (KR)

(21) Appl. No.: 12/012,268

(22) Filed: Feb. 1, 2008

(30) Foreign Application Priority Data
Feb. 2, 2007 (KR) 10-2007-0011090

(51) Int. Cl. H01L 21/66

(52) U.S. Cl. 438/17; 257/E21.531

(57) ABSTRACT

A method of sorting dies using a discrimination region includes preparing a wafer including a chip region in which a plurality of dies are disposed and an edge region in which at least one discrimination region is disposed; testing the dies to prepare a wafer map for defining the coordinates of good dies and bad dies; allowing dies defined by the wafer map to correspond to the dies of the wafer; and confirming the correctness of the correspondence between the wafer and the wafer map by checking whether the discrimination region is included in the dies defined by the wafer map.

This application claims priority to Korean Patent Application No. 10-2007-0011090, filed in the Korean Intellectual Property Office on Feb. 2, 2007, the entire contents of which are hereby incorporated herein by reference.

### BACKGROUND OF THE INVENTION

1. Field of the Invention

The present invention relates to a method of fabricating a semiconductor device, and more particularly, to a method of sorting dies using a discrimination region.

2. Description of the Related Art

A semiconductor device is fabricated using a wafer with a plurality of dies. The dies are separated using a wafer sawing process and undergo a packaging process to fabricate individual semiconductor chips. In general, all of the dies do not operate properly due to variations in the fabrication process. Therefore, it is necessary to sort normally operating dies (hereinafter, “good” dies), that is, distinguish good dies from abnormally operating (hereinafter, “bad”) dies. A process of sorting the good dies is performed using a predetermined electrical test, and only good dies that have passed the electrical test can be fabricated as semiconductor chips using the packaging process. Bad dies are discarded.

When the sorting process is not properly performed, bad dies may be packaged, while good dies may be discarded. In order to avoid a drop in yield and the degradation of the reliability of manufacturing companies due to this improper performance of the sorting process, it is required to precisely sort good dies and package only the sorted good dies. Conventionally, an inking method is used to indicate a failure on a top surface a die with an ink mark. However, for a wafer with small thickness and large area, the inking method may damage the wafer, and so, the ink method has recently been replaced by an inkless sorting method.

An inkless sorting method used for a packaging process includes providing a wafer map for defining the coordinates of good dies and bad dies corresponding to an actual wafer. In this case, the wafer map, i.e., the coordinates of the good and bad dies, is obtained using the electrical test. However, since the packaging process is performed at a different time, i.e., in a different process step, and in a different place, i.e., in a different system, from the electrical test, for a wafer having a plurality of dies, there is still a possibility of incorrect correspondence between a wafer map 20 and an actual wafer 10 as illustrated in FIG. 1. This incorrect correspondence can be caused by operator error. Therefore, it is necessary to develop a new method of enabling efficient, correct correspondence between a wafer map and an actual wafer in order to prevent yield and the reliance of customers on manufacturers from dropping.

### SUMMARY OF THE INVENTION

The present invention provides a method of enabling correct correspondence between a wafer map and an actual wafer.

Also, the present invention provides a method of enabling efficient correspondence between a wafer map and an actual wafer.

According to an aspect of the present invention, there is provided a method of sorting dies. The method includes preparing a wafer including a chip region in which a plurality of dies are disposed and an edge region in which at least one discrimination region is disposed. The dies are tested to prepare a wafer map for defining the coordinates of good dies and bad dies. Dies defined by the wafer map are allowed to correspond to the dies of the wafer. The correctness of the correspondence between the wafer and the wafer map is confirmed by determining whether the discrimination region is included in the dies defined by the wafer map.

According to the present invention, allowing the dies defined by the wafer map to correspond to the dies of the wafer may include selecting a map reference die from the dies defined by the wafer map; and selecting a wafer reference die corresponding to the map reference die from the dies of the wafer.

Also, confirming the correctness of the correspondence between the wafer and the wafer map may include: selecting at least one check die from the dies defined by the wafer map; checking whether or not the check die corresponds with the discrimination region; determining that the correspondence between the wafer and the wafer map is incorrect when the check die corresponds with the discrimination region; and determining that the correspondence between the wafer and the wafer map is correct when the check die does not correspond with the discrimination region. In this case, when determining that the correspondence between the wafer and the wafer map is incorrect, a new wafer reference die corresponding to the map reference die may be selected from the dies of the wafer, and the correctness of the correspondence between the wafer and the wafer map may be reconfirmed.

The selection of the new wafer reference die may include: calculating a distance of misalignment based on the coordinates of the check die and the discrimination region; and selecting the new wafer reference die based on the calculated distance of misalignment.

In an embodiment of the present invention, the dies disposed in the chip region may have metal patterns, and the discrimination region may be entirely covered with a metal layer to optically discriminate the discrimination region from the metal patterns. In this case, checking whether the check die corresponds with the discrimination region may include analyzing optical properties measured at the coordinates of the check die.

According to the present invention, the wafer may have a direction indicator for displaying the direction of the wafer, the dies of the wafer may be 2-dimensionally arranged in the chip region such that the positions of the dies are defined by x-y coordinates. In this case, the coordinates of the dies of the wafer may be defined on the basis of the direction indicator. Also, the map reference die may be selected from the dies adjacent to both the direction indicator and the discrimination region.

The check die may be selected from the dies disposed on an edge of the chip region. Specifically, the check die may include at least one selected from dies having the smallest x coordinate, dies having the largest x coordinate, dies having the largest y coordinate, and dies having the smallest y coordinate. More specifically, the check die may include at least one selected from a die having the largest y coordinate of the dies having the smallest x coordinate, a die having the smallest y coordinate of the dies having the smallest x coordinate, a die having the largest y coordinate of the dies having the largest x coordinate, a die having the smallest y coordinate of the dies having the largest x coordinate, a die having the smallest x coordinate of the dies having the largest y coordinate, a die having the largest x coordinate of the dies having the largest y coordinate, a die having the smallest x coordinate of the dies having the smallest y coordinate, and a die having the largest x coordinate of the dies having the smallest y coordinate.

The discrimination region may be disposed in an edge region of the wafer adjacent to the check die.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a diagram illustrating an example of incorrect correspondence between a wafer map and an actual wafer.

FIG. 2 is a process flowchart illustrating a method of fabricating a semiconductor device according to an embodiment of the present invention.

FIG. 3 is a process flowchart illustrating a method of sorting dies according to an embodiment of the present invention.

FIGS. 4 through 7 are diagrams illustrating methods of selecting reference dies and check dies and a method of forming a selection region according to embodiments of the present invention.

FIG. 8 is a diagram of a selection region according to an embodiment of the present invention.

FIG. 9 is a diagram illustrating a method of discriminating a check die according to an embodiment of the present invention.

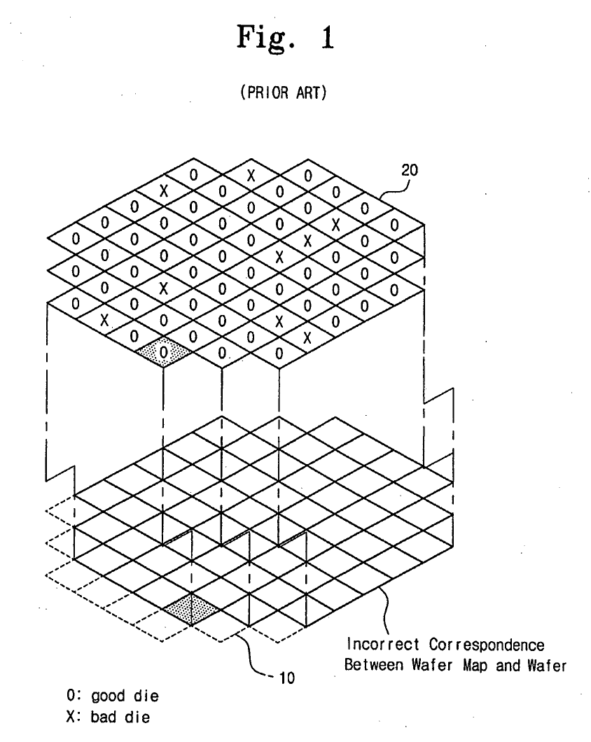

### DETAILED DESCRIPTION OF THE INVENTION

Reference will now be made in detail to the preferred embodiments of the present invention, examples of which are illustrated in the accompanying drawings.

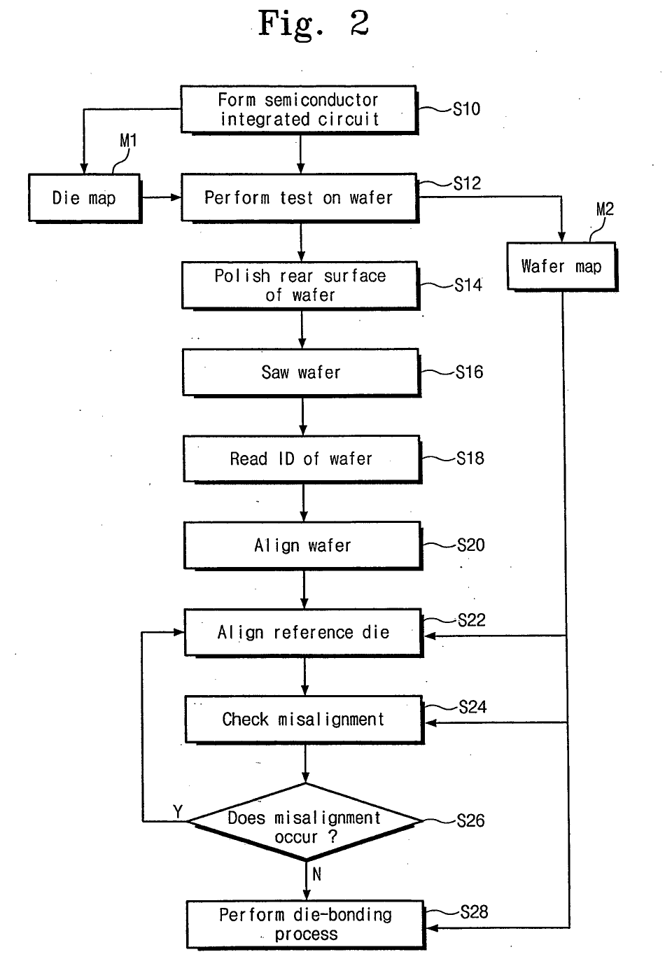

It will be understood that when a layer is referred to as being “on” another layer or substrate, it can be directly on the other layer or substrate, or intervening layers may also be present. In the drawings, the thicknesses of layers and regions are exaggerated for clarity. It will be understood that although the terms first and second are used herein to describe various regions, layers and/or sections should not be limited by these terms. These terms are only used to distinguish one region, layer or section from another region, layer or section. Thus, for example, a first layer discussed below could be termed a first layer without departing from the teachings of the present invention. Each embodiment described and illustrated herein includes complementary embodiments thereof FIG. 2 is a process flowchart illustrating a method of fabricating a semiconductor device according to an embodiment of the present invention.

Referring to FIG. 2, a semiconductor integrated circuit is formed on a wafer having a plurality of dies in step S10. The wafer includes a chip region in which the dies are disposed and an edge region disposed around the chip region. At least one discrimination region is disposed in the edge region.

The dies are 2-dimensionally arranged on the wafer laid on the x-y plane, and the x-y coordinates of the dies are stored in the form of a die map M1. Thereafter, an electrical test is performed on each of the dies defined by the die map M1 so that a test result is stored in a wafer map M2 in step S12. In this case, the wafer map M2 is prepared to include the identification (ID) of the tested wafer, the coordinates of each of the dies, and information on the presence or absence of failures.

Thereafter, a rear surface of the wafer is polished to reduce the thickness of the wafer in step S14. As a result, the dies of the wafer have an appropriate thickness for a packaging process. Subsequently, the wafer is sawed along a scribe lane between the dies to separate the dies in step S16, and the ID of the wafer is read to select the wafer map M2 corresponding to the wafer in step S18. The wafer is loaded into a sorter for sorting good dies, and the loaded wafer is aligned in an appropriate position and direction for a sorting process in step S20. According to modified embodiments of the present invention, step S14 of polishing the wafer, step S16 of sawing the wafer, step S18 of reading the ID of the wafer, and step S20 of aligning the wafer may be performed in various orders other than as described above. For example, step S20 of aligning the wafer may be followed by step S18 of reading the ID of the wafer.

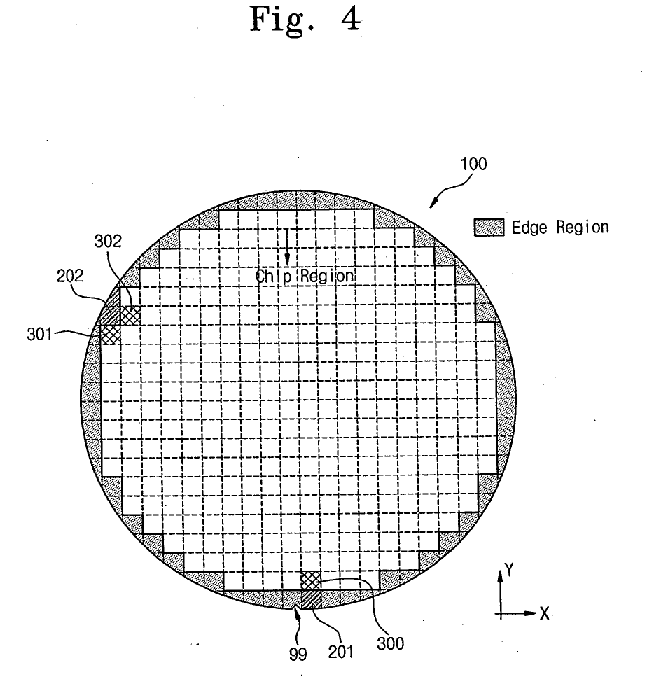

Thereafter, the loaded wafer is allowed to correspond to the wafer map M2. In this case, since the wafer is an actual object and the wafer map M2 is virtual information, the wafer cannot be physically connected to the wafer map M2 but it is only possible to set up a relationship between the coordinates of the wafer and the wafer map M2. In the present invention, an expression “allowing a wafer to correspond to a wafer map” means a process of establishing a relationship between the coordinates of the wafer and the wafer map. According to the present invention, the process of allowing the wafer to correspond to the wafer map M2 includes step S22 of allowing a predetermined reference die (hereinafter, a map reference die) selected out of the dies defined by the wafer map M2 to correspond to a die (hereinafter, a wafer reference die) of the wafer, which has the coordinates corresponding to the reference die. A method of selecting the map reference die or the wafer reference die will be described again with reference to FIGS. 4 through 7.

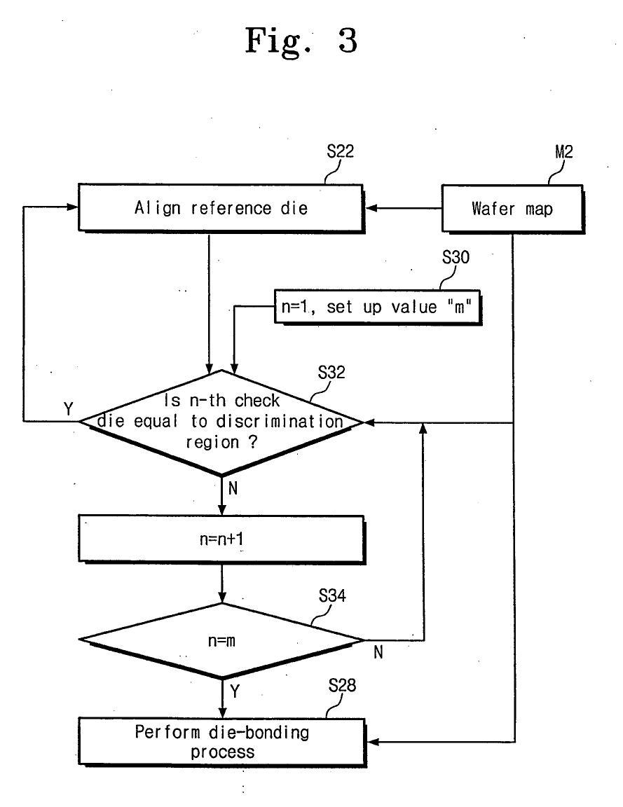

As described in Background of the Invention, the correspondence between the map reference die and the wafer reference die may be temporary due to operator's confusion or an error of equipment. In other words, the selected wafer reference die may not be a die defined by the map reference die. Therefore, a misalignment check for confirming whether or not incorrect correspondence between the map reference die and the wafer reference die occurs is performed in step S24 after step S22 of aligning the map reference die with the wafer reference die. The misalignment check (step S24) will be described in more detail below with reference to FIG. 3.

According to the present invention, step S22 of aligning the map reference die with the wafer reference die and step S24 of making the misalignment check are repeated in step S26 until it is confirmed that no misalignment between the wafer map M2 and the wafer occurs. Thereafter, when it is confirmed that no misalignment between the wafer map M2 and the wafer occurs, a die-bonding process is performed in step S28. The die-bonding process (step S28) is selectively performed on the dies of the wafer, which are located at the coordinates of good dies recorded by the wafer map M2. The die-bonding process may include transferring the selected dies to a system in which a packaging process will be performed.

FIG. 3 is a process flowchart illustrating a method of sorting good dies according to an embodiment of the present invention, and FIGS. 4 through 7 are diagrams illustrating methods of selecting reference dies and check dies and a method of forming a selection region according to embodiments of the present invention.

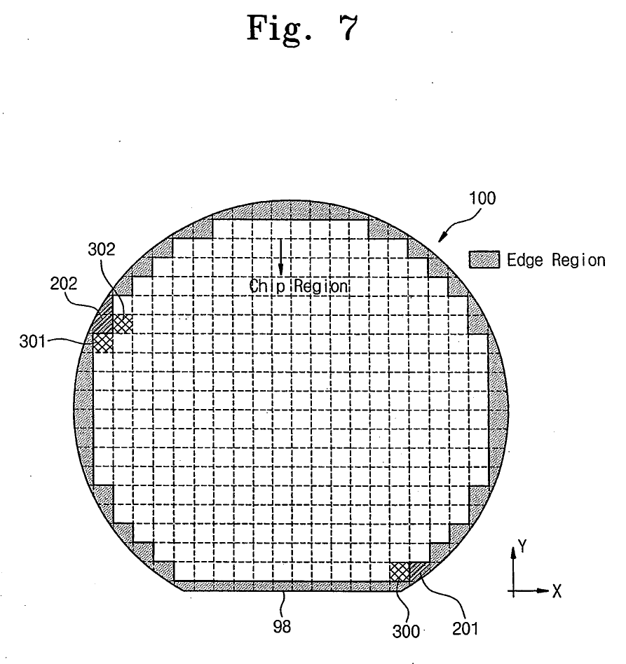

As is known, a wafer 100 has a direction indicator for indicating the direction thereof. For example, the direction indicator may be a notch 99 formed at an edge of the wafer 100 as illustrated in FIGS. 4 through 6 or a flat zone 98 illustrated in FIG. 7.

Referring to FIGS. 3 and 4, a wafer reference die 300 corresponding to a selected map reference die is selected out of dies of the wafer 100 in step S22 in the same manner as described with reference to FIG. 2. According to the present invention, the map reference die and the wafer reference die 300 may be selected in the vicinity of the direction indicator. For example, as illustrated in FIGS. 4 through 6, each of the map reference die and the wafer reference die 300 may be a die selected from dies adjacent to the notch 99. According to the present invention, a reference discrimination region 201 may be formed adjacent to the notch 99 in order to reduce operator's confusion during the above-described reference selection process. Thus, a die of a chip region that is most adjacent to the reference discrimination region 201 may be selected as each of the map reference die and the wafer reference die 300.

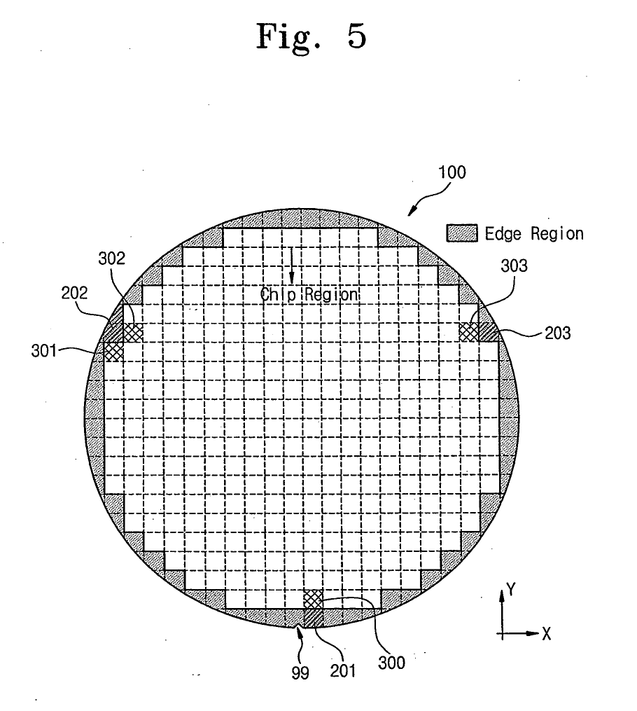

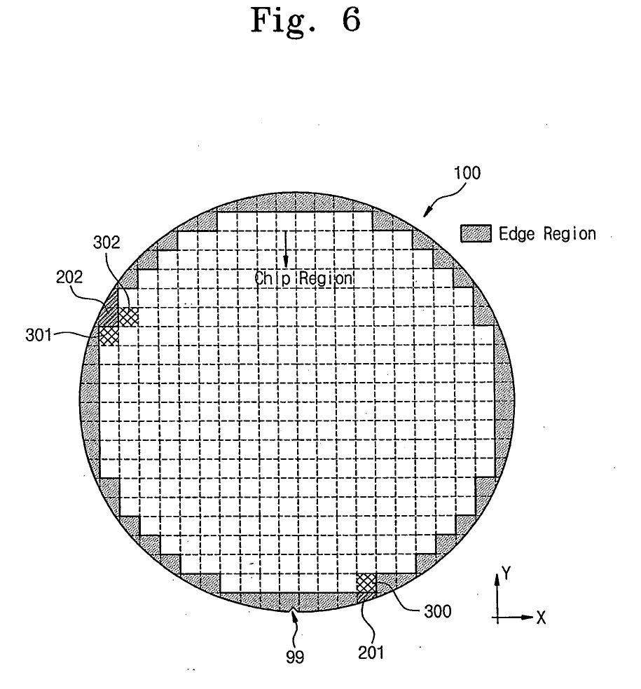

The map reference die and the wafer reference die 300 are selected to set a standard for precisely allowing the wafer 100 to correspond to a wafer map. Thus, the map reference die and the wafer reference die 300 may be selected using various methods. For example, as illustrated in FIG. 6, a die spaced apart from the notch 99 may be selected as the map reference die or the wafer reference die 300, in contrast with the method described in connection with reference to FIGS. 4 and 5. Irrespective of how to select the map reference die and the wafer reference die 300, the map reference die and the wafer reference die 300 may be employed to precisely allow the wafer 100 to correspond to the wafer map. However, in order to minimize operator's confusion, the map reference die and the wafer reference die 300 may be selected on the basis of the direction indicator of the wafer 100 because the direction indicator is easily discriminable.

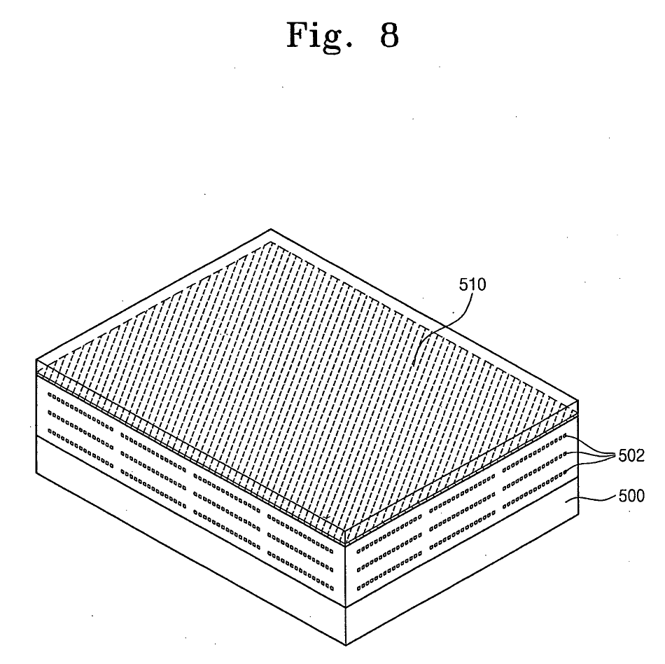

According to the present invention, at least one of discrimination regions 202 and 203 is disposed at an edge region of the wafer 100 as described above. The discrimination regions 202 and 203 may be optically discriminated from other portions of the edge region or dies of the chip region. For example, as illustrated in FIG. 8, a metal layer 510 is formed over a semiconductor substrate 500 on the entire surfaces of the discrimination regions 202 and 203, and the dies include metal patterns formed at substantially the same level with the metal layer 510. A difference between the discrimination regions 202 and 203 and the dies causes an optical difference recognized by an operator or a system. In order to make the difference, after forming a photoresist pattern on the entire surfaces of the discrimination regions 202 and 203, a patterning process may be performed using the photoresist pattern to form the metal patterns of the dies. When the metal layer 510 is formed on the entire surfaces of the discrimination regions 202 and 203, the discrimination regions 202 and 203 have as high a reflectance as a mirror so that the discrimination regions 202 and 203 can be called mirror regions. However, the discrimination regions 202 and 203 according to the present invention are not limited to the mirror regions and may have other optically discriminable structures.

As described above, the edge region is disposed outside the chip region in which the dies are disposed and a wafer map M2 includes information on the dies of the chip region. Thus, the discrimination regions 202 and 203 are not included in the wafer map M2. Thus, after selecting a die adjacent to the discrimination regions 202 and 203 as a check die, it may be confirmed whether or not the discrimination regions 202 and 203 are included in the check die of the wafer map M2 so that the correctness of the correspondence between the map reference die and the wafer reference die 300 can be known.

More specifically, referring again to FIG. 3, at least one of check dies 301, 302, and 303 is selected and then it is confirmed whether or not the check die is equal to a discrimination region adjacent to the check die in step S32. That is, a determination is made as to whether one of the check dies 301, 302 and 303 includes, corresponds with, or is in the same position, i.e., has the same coordinates as, one or more of the discrimination regions The number of dies selected as the check dies may be changed if required. In one embodiment, the number of check dies is 2, 3, or 4. In FIG. 3, reference character “n” denotes an iteration variable that expresses the order of the misalignment check (step S24), and “m” denotes the number of the dies selected as the check dies.

As described above, since the discrimination regions 202 and 203 are part of the edge region, when the correspondence between the map reference die and the wafer reference die 300 is correct, a measurement result that the check die does not correspond with the discrimination regions 202 and 203 should be obtained. Therefore, when it is determined that at least one of the check dies 301, 302, and 303 is equal to the discrimination regions 202 and 203, it may be concluded that step S22 of aligning the map reference die with the wafer reference die 300 is erroneous. In this case, step S22 of aligning the map reference die with the wafer reference die 300 is performed again to select a new wafer reference die 300. The selection of the new wafer reference die 300 includes calculating a difference in the coordinates between the check die and the discrimination region (i.e., a distance of misalignment) and selecting a die with new coordinates required for correct correspondence between the wafer 100 and the wafer map based on the distance of misalignment as the new wafer reference die 300. Thereafter, it is confirmed whether all the check dies correspond with the discrimination regions in step S34. When it is confirmed that all the check dies do not correspond with the discrimination regions, the die-bonding process (step S28) is performed.

The check dies may be freely selected like the reference dies. However, a method of minimizing the number of check dies and elevating the accuracy of a misalignment checking process is used to improve the efficiency of the misalignment checking process.

According to the present invention, the check die may be selected from the dies disposed on the edge of the chip region. That is, the check die may be selected from the dies that contact the edge region. For example, as illustrated in FIGS. 4 through 7, the check die may be selected from the dies that contact the discrimination regions 202 and 203. Since the distance of misalignment is mostly not great, when the check die is selected from the dies that contact the edge region, the efficiency of the misalignment checking process can be enhanced.

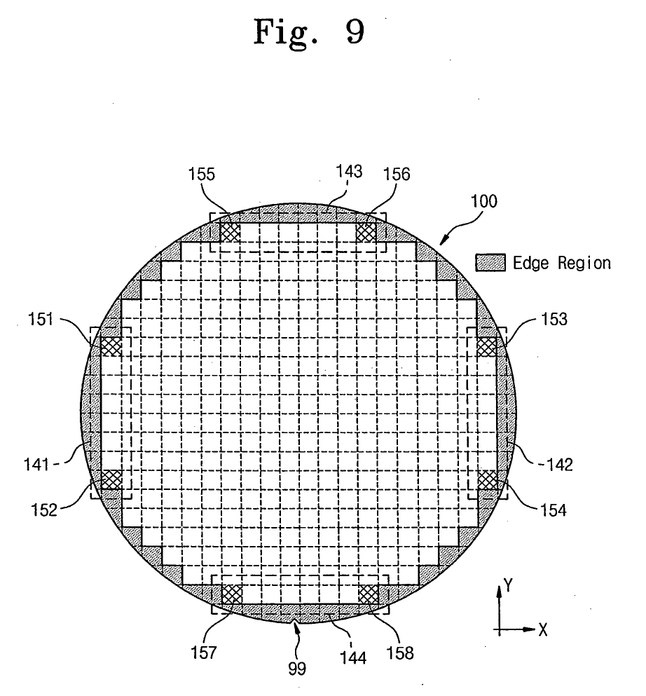

FIG. 9 is a diagram illustrating a method of discriminating a check die according to an embodiment of the present invention.

Referring to FIG. 9, as described above, dies are 2-dimensionally arranged on a wafer 100 laid on the x-y plane, and the x-y coordinates of the dies are stored in the shape of a die map M1. In this case, the coordinates of the dies may be defined on the basis of a direction indicator. In this case, a check die may be at least one of dies 141 having the smallest x 10 coordinate, dies 142 having the largest x coordinate, dies 143 having the largest y coordinate, and dies 144 having the largest y coordinate. When selecting the check die from the dies 141, 142, 143, and 144, since the location of the check die can be easily confirmed, confusion can be reduced and the efficiency of a misalignment check can be enhanced.

More specifically, the check die may be at least one selected from a die 151 having the largest y coordinate of the dies 141 having the smallest x coordinate, a die 152 having the smallest y coordinate of the dies 141 having the smallest x coordinate, a die 153 having the largest y coordinate of the dies 142 having the largest x coordinate, a die 154 having the smallest y coordinate of the dies 142 having the largest x coordinate, a die 155 having the smallest x coordinate of the dies 143 having the largest y coordinate, a die 156 having the largest x coordinate of the dies 143 having the largest y coordinate, a die 157 having the smallest x coordinate of the dies 144 having the smallest y coordinate, and a die 158 having the largest x coordinate of the dies 144 having the smallest y coordinate.

According to the present invention, the discrimination regions may be formed in an edge region adjacent to the check dies formed using the above-described method. In this case, as illustrated in FIGS. 4 through 7, a second check die 302 adjacent to the discrimination region 202 may be further selected in the vicinity of a first check die (e.g., the check die 301) selected using the above-described method. Referring to FIGS. 4 through 7, the first check die 301 is used to check a case where the wafer map is misaligned from the wafer 100 in a positive y-direction, and the second check die 302 may be used to check a case where the wafer map is misaligned from the wafer 100 in a negative x-direction.

According to another embodiment of the present invention, as illustrated in FIG. 5, a third discrimination region 203 may be formed in an upper right region of a wafer, and a third check die 303 may be formed on the left of the third discrimination region 203 and used to confirm a case where the wafer map is misaligned from the wafer 100 in a positive x-direction.

According to yet another embodiment of the present invention, as illustrated in FIGS. 4 and 5, a wafer reference die 300 formed over a reference discrimination region 201 may be used to confirm a case where the wafer map is misaligned from the wafer 100 in a negative y-direction. Also, as illustrated in FIG. 7, the reference discrimination region 201 and the wafer reference die 300 may be used to confirm a case where the wafer map is misaligned from the wafer 100 in a positive x-direction.

According to the present invention, it is easily and effectively confirmed using a discrimination region whether or not the correspondence between a wafer and a wafer map is correct. Thus, a reduction in yield and a drop in the reliance of customers on products due to incorrect correspondence between the wafer and the wafer map can be minimized.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of sorting dies comprising:
preparing a wafer including a chip region in which a plurality of dies are disposed and an edge region in which at least one discrimination region is disposed;
testing the dies to prepare a wafer map for defining the coordinates of good dies and bad dies;
allowing dies defined by the wafer map to correspond to the dies of the wafer; and
confirming the correctness of the correspondence between the wafer and the wafer map by determining whether the discrimination region is included in the dies defined by the wafer map.

2. The method according to claim 1, wherein allowing the dies defined by the wafer map to correspond to the dies of the wafer comprises:
selecting a map reference die from the dies defined by the wafer map; and
selecting a wafer reference die corresponding to the map reference die from the dies of the wafer.

3. The method according to claim 2, wherein confirming the correctness of the correspondence between the wafer and the wafer map comprises:
selecting at least one check die from the dies defined by the wafer map;
checking whether the check die corresponds with the discrimination region;
determining that the correspondence between the wafer and the wafer map is incorrect when the check die corresponds with the discrimination region; and
determining that the correspondence between the wafer and the wafer map is correct when the check die is not equal to the discrimination region.

4. The method according to claim 3, when determining that the correspondence between the wafer and the wafer map is incorrect, further comprising:
selecting a new wafer reference die corresponding to the map reference die from the dies of the wafer; and
reconfirming the correctness of the correspondence between the wafer and the wafer map.

5. The method according to claim 3, wherein selecting the new wafer reference die comprises:
calculating a distance of misalignment based on the coordinates of the check die and the discrimination region; and
selecting the new wafer reference die based on the calculated distance of misalignment.

6. The method according to claim 3, wherein the dies disposed in the chip region have metal patterns, and the discrimination region is entirely covered with a metal layer to optically discriminate the discrimination region from the metal patterns,
wherein checking whether the check die corresponds with the discrimination region comprises analyzing optical properties measured at the coordinates of the check die.

7. The method according to claim 3, wherein the wafer has a direction indicator for displaying the direction of the wafer,
the dies of the wafer are 2-dimensionally arranged in the chip region such that the positions of the dies are defined by x-y coordinates,
and the coordinates of the dies of the wafer are defined on the basis of the direction indicator.

8. The method according to claim 7, wherein the map reference die is selected from the dies adjacent to both the direction indicator and the discrimination region.

9. The method according to claim 7, wherein the check die is selected from the dies disposed on an edge of the chip region.

10. The method according to claim 9, wherein the check die includes at least one selected from dies having the smallest x coordinate, dies having the largest x coordinate, dies having the largest y coordinate, and dies having the smallest y coordinate.

11. The method according to claim 10, wherein the check die includes at least one selected from a die having the largest y coordinate of the dies having the smallest x coordinate, a die having the smallest y coordinate of the dies having the smallest x coordinate, a die having the largest y coordinate of the dies having the largest x coordinate, a die having the smallest y coordinate of the dies having the largest x coordinate, a die having the smallest x coordinate of the dies having the largest y coordinate, a die having the largest x coordinate of the dies having the largest y coordinate, a die having the smallest x coordinate of the dies having the smallest y coordinate, and a die having the largest x coordinate of the dies having the smallest y coordinate.

12. The method according to claim 10, wherein the discrimination region is disposed in an edge region of the wafer adjacent to the check die.
